(19) United States
(12) Patent Application Publication
(10) Pub. No.: US 2025/0380490 A1
(43) Pub. Date: Dec. 11, 2025

(54) SEMICONDUCTOR DEVICE

(71) Applicant: FUJI ELECTRIC CO., LTD., Kanagawa (JP)

(72) Inventor: Kosuke YOSHIDA, Matsumoto-city (JP)

(21) Appl. No.: 19/185,116

(22) Filed: Apr. 21, 2025

(30) Foreign Application Priority Data
Jun. 6, 2024 (JP) 2024-091949

(51) Int. Cl. H10D 84/00; H10D 12/00; H10D 62/10

(52) U.S. Cl. CPC H10D 84/161; H10D 12/415; H10D 62/107; H10D 12/481

(57) ABSTRACT

Provided is a semiconductor device including a drift region of a first conductivity type which is provided in a semiconductor substrate, a plurality of trench portions which have a gate trench portion and a dummy trench portion and are arranged at a predetermined pitch in a trench array direction, and an outer circumferential well region of the second conductivity type which is provided on an outer circumference of the semiconductor substrate relative to the plurality of trench portions, in which the plurality of trench portions are provided to be spaced apart from the outer circumferential well region, and a difference between an end portion of the gate trench portion and an end portion of the dummy trench portion in a trench extension direction is less than or equal to twice the pitch.

The contents of the following patent application(s) are incorporated herein by reference: NO. 2024-091949 filed in JP on Jun. 6, 2024.

### BACKGROUND

### 1. Technical Field

The present invention relates to a semiconductor device.

### 2. Related Art

Patent Document 1 describes “a first buffer region 20 is formed to be thicker than a second buffer region 22, so that a breakdown voltage in an active section 80 can be lowered.” (0035). Patent Document 2 describes “a gate runner 130 may be provided above an outer circumferential well region 11. A gate polysilicon 46 may be provided below the gate runner 130.” (0065).

### PRIOR ART DOCUMENTS

### Patent Documents

Patent Document 1: Japanese Patent Application Publication No. 2018-133493
Patent Document 2: WO2022/158053

### BRIEF DESCRIPTION OF THE DRAWINGS

FIG. 1 is a top view illustrating an example of a semiconductor device 100 according to an embodiment of the present invention.

FIG. 2 is an enlarged view of a region D1 in FIG. 1.

FIG. 3 illustrates an example of a cross section a-a in FIG. 2.

FIG. 4 illustrates an example of a cross section b-b in FIG. 2.

FIG. 5 is an enlarged view of an area in a vicinity of a trench contact portion 58 in a boundary region 200.

FIG. 6 is an enlarged view of a region D2 in FIG. 1.

FIG. 7 illustrates an example of a cross section c-c in FIG. 6.

FIG. 8 illustrates an example of a cross section d-d in FIG. 6.

FIG. 9 illustrates an example of a cross section e-e in FIG. 6.

FIG. 10 illustrates an example of a cross section f-f in FIG. 6.

FIG. 11 illustrates another example of the cross section c-c in FIG. 6.

FIG. 12 illustrates another example of the cross section d-d in FIG. 6.

FIG. 13 illustrates another example of the cross section f-f in FIG. 6.

FIG. 14 is a graph representing a relationship of a breakdown voltage [a.u.] with respect to a distance [a.u.] between a trench portion and an outer circumferential well region according to the semiconductor device 100 and a comparative example.

### DESCRIPTION OF EXEMPLARY EMBODIMENTS

Hereinafter, the present invention will be described by way of embodiments of the invention. However, the following embodiments are not for limiting the invention according to the claims. In addition, not all of the combinations of features described in the embodiments are essential to the solution of the invention.

In the present specification, technical matters may be described using orthogonal coordinate axes of an X axis, a Y axis, and a Z axis. The orthogonal coordinate axes merely specify relative positions of components and do not limit a specific direction. For example, the Z axis is not limited to indicate a height direction with respect to a ground. It should be noted that a +Z axis direction and a −Z axis direction are directions opposite to each other. If the Z axis direction is described without describing the signs, it means that the direction is parallel to the +Z axis and the −Z axis.

In the present specification, orthogonal axes parallel to an upper surface and a lower surface of a semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with an impurity is described as a P type or an N type. A conductivity type of the P type may be referred to as a second conductivity type, and a conductivity type of the N type may be referred to as a first conductivity type. In the present specification, the impurities may particularly mean either a donor of the N type or an acceptor of the P type and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration in any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by a combination of at least a vacancy (V) and hydrogen (H). Alternatively, interstitial Si—H which is a combination of interstitial silicon (Si-i) and hydrogen in a silicon semiconductor also functions as the donor which supplies electrons. In the present specification, the VOH defect or interstitial Si—H may be referred to as a hydrogen donor.

In the semiconductor substrate in the present specification, a bulk donor of the N type is distributed throughout. The bulk donor is a dopant donor substantially uniformly contained in an ingot during the manufacture of the ingot from which the semiconductor substrate is made. The bulk donor in this example is an element other than hydrogen. The bulk donor dopant is, for example, phosphorous, antimony, arsenic, selenium, or sulfur but is not limited to these. The bulk donor in this example is phosphorous. The bulk donor is also contained in a region of the P type. The semiconductor substrate may be a wafer cut out from a semiconductor ingot or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in a substrate manufactured by the MCZ method is 1×10¹⁷ to 7×10¹⁷/cm³. An oxygen concentration contained in a substrate manufactured by the FZ method is 1×10¹⁵ to 5×10¹⁶/cm³. As the oxygen concentration is higher, hydrogen donors tend to be more easily generated. The bulk donor concentration may use a chemical concentration of the bulk donor distributed throughout the semiconductor substrate or may be set as a value from 90% to 100% of the chemical concentration. In addition, as the semiconductor substrate, a non-doped substrate not containing a dopant such as phosphorous may be used. In that case, the bulk donor concentration (DO) of the non-doped substrate is, for example, greater than or equal to 1×10¹⁰/cm³ and less than or equal to 5×10¹²/cm³. The bulk donor concentration (DO) of the non-doped substrate is preferably greater than or equal to 1×10¹¹/cm³. The bulk donor concentration (DO) of the non-doped substrate is preferably less than or equal to 5×10¹²/cm³. Each concentration in the present invention may be set as a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before some calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be set as a value in a thermal equilibrium state. In addition, in a region of the N type, the donor concentration is sufficiently greater than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping. In the present specification, atoms/cm³ or/cm³ is used to indicate a concentration per unit volume. This unit is used for a donor or acceptor concentration in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder of a crystal structure (disorder) due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

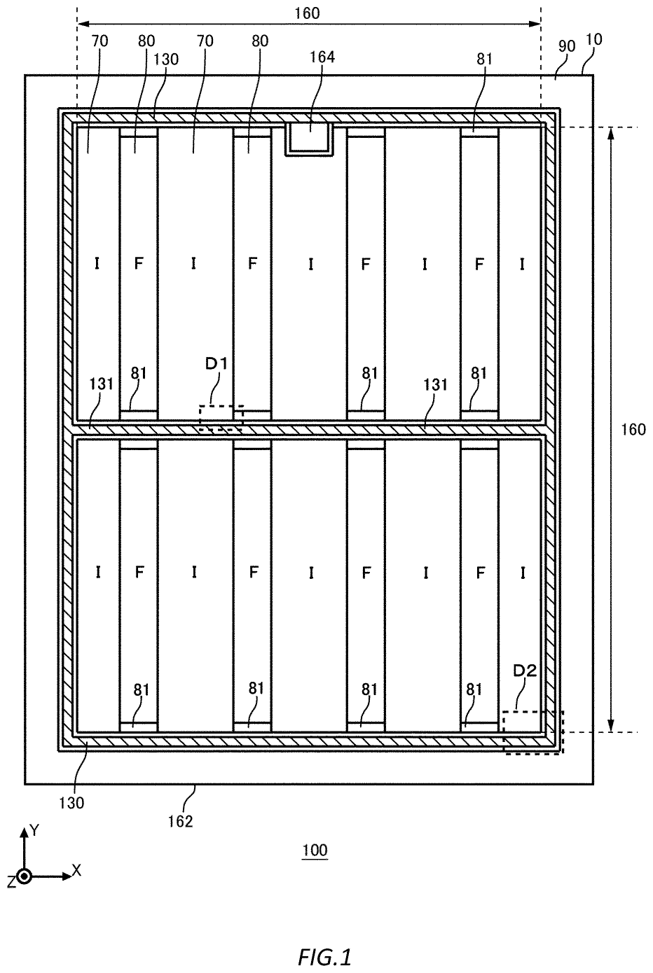

FIG. 1 is a top view illustrating an example of a semiconductor device 100 according to an embodiment of the present invention. FIG. 1 illustrates a position of each member projected onto an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When the top view is simply mentioned in the present specification, it means that the semiconductor substrate 10 is viewed from an upper surface side. The semiconductor substrate 10 in this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active section 160. The active section 160 is a region where a main current flows in a depth direction between the upper surface and a lower surface of the semiconductor substrate 10 when the semiconductor device 100 operates. An emitter electrode is provided above the active section 160 but is omitted in FIG. 1. The active section 160 may refer to a region which overlaps the emitter electrode in the top view. In addition, a region sandwiched between active sections 160 in the top view may also be included in the active section 160.

The active section 160 is provided with a transistor section 70 including a transistor element such as an insulated gate bipolar transistor (IGBT) and a diode section 80 including a diode element such as a freewheeling diode (FWD). In the example of FIG. 1, the transistor sections 70 and the diode sections 80 are alternately arranged along a predetermined first direction (X axis direction in this example) on the upper surface of the semiconductor substrate 10. The semiconductor device 100 in this example is a reverse conduction type IGBT (RC-IGBT). The semiconductor device 100 may be a single IGBT. A boundary region may be arranged between the transistor section 70 and the diode section 80 in the X axis direction but is omitted in FIG. 1.

In FIG. 1, a region where each of the transistor sections 70 is arranged is indicated by a symbol “I”, and a region where each of the diode sections 80 is arranged is indicated by a symbol “F”. In the present specification, a direction different from the first direction in the top view may be referred to as a second direction (Y axis direction in FIG. 1). The second direction may be a direction perpendicular to the first direction. Each of the transistor section 70 and the diode section 80 may have a longitudinal length in the second direction. In other words, a length of the transistor section 70 in the Y axis direction is larger than a width in the X axis direction. Similarly, a length of the diode section 80 in the Y axis direction is larger than a width in the X axis direction. The second direction of the transistor section 70 and the diode section 80 may be the same as a longitudinal direction of each trench portion and a longitudinal direction of the mesa portions described below.

The transistor section 70 has the collector region of the P+ type in a region in contact with the lower surface of the semiconductor substrate 10. In the present specification, a region where the collector region is provided is referred to as the transistor section 70. In other words, the transistor section 70 is a region which overlaps the collector region in the top view. The diode section 80 has a cathode region of the N+ type in a region in contact with the lower surface of the semiconductor substrate 10. In the present specification, a region where the cathode region is provided is referred to as the diode section 80. In other words, the diode section 80 is a region which overlaps the cathode region in the top view. On the lower surface of the semiconductor substrate 10, a collector region of the P+ type may be provided in a region other than the cathode region. In the present specification, the diode section 80 may also include an extension region 81 where the diode section 80 extends to a gate runner described below in the Y axis direction. The collector region is provided on a lower surface of the extension region 81.

The semiconductor device 100 may have one or more pads above the semiconductor substrate 10. The semiconductor device 100 in this example has a gate pad 164. A gate potential is applied to the gate pad 164. The gate pad 164 is electrically connected to a conductive portion of a gate trench portion of the active section 160. Note that the semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. When the semiconductor device 100 is mounted, each pad may be connected to an external circuit via a runner such as a wire.

The semiconductor device 100 includes a gate runner arranged above the semiconductor substrate 10. The gate runner may be a metal runner containing aluminum or the like or a runner formed of a semiconductor such as polysilicon doped with an impurity.

The gate runner connects the gate pad 164 and the gate trench portion. That is, the gate runner is connected to the gate pad 164 and connected to the gate trench portion of the active section 160. In FIG. 1, the gate runner is hatched with diagonal lines. The gate runner is an example of a gate metal layer connected to the gate trench portion.

The gate runner in this example has an outer circumferential gate runner 130 and an active-side gate runner 131. The outer circumferential gate runner 130 is arranged between the active section 160 and the end side 162 of the semiconductor substrate 10 in the top view. The outer circumferential gate runner 130 in this example surrounds the active section 160 in the top view. A region surrounded by the outer circumferential gate runner 130 in the top view may be set as the active section 160. The outer circumferential gate runner 130 is connected to the gate pad 164.

The active-side gate runner 131 is provided in the active section 160. Providing the active-side gate runner 131 in the active section 160 can reduce a variation in a runner length from the gate pad 164 for each region of the semiconductor substrate 10.

The active-side gate runner 131 may be connected to the outer circumferential gate runner 130. The active-side gate runner 131 in this example is provided extending in the X axis direction so as to cross the active section 160 from one outer circumferential gate runner 130 to another outer circumferential gate runner 130 which sandwich the active section 160 so that the active section 160 is divided into approximately equal parts in the Y axis direction. When the active section 160 is divided by the active-side gate runner 131, the transistor sections 70 and the diode sections 80 may be alternately arranged in the X axis direction in each divided region.

An outer circumferential well region is formed below the gate runner. The outer circumferential well region is a P type region with a concentration higher than that of a base region described below and is formed from the upper surface of the semiconductor substrate 10 to a position deeper than the base region. A region surrounded by the outer circumferential well region in the top view may be set as the active section 160. That is, the outer circumferential well region is a region of a conductivity type of the P type which is provided on an outer circumference of the semiconductor substrate 10 relative to a plurality of trench portions of the active section 160. The outer circumferential well region may have a concentration equivalent to that of the base region.

The semiconductor device 100 may include a temperature sensing portion (not illustrated) that is a PN junction diode formed of polysilicon or the like, and a current detection portion (not illustrated) that simulates an operation of the transistor section provided in the active section 160. Note that the temperature sensing portion may be connected to an anode pad and a cathode pad arranged in a vicinity of the end side 162.

The semiconductor device 100 in this example includes an edge termination structure portion 90 between the active section 160 and the end side 162 in the top view. The edge termination structure portion 90 in this example is arranged between the outer circumferential gate runner 130 and the end side 162. The edge termination structure portion 90 relaxes an electric field strength on the upper surface side of the semiconductor substrate 10. The edge termination structure portion 90 may include at least one of a guard ring, a field plate, or a RESURF which are annularly provided surrounding the active section 160.

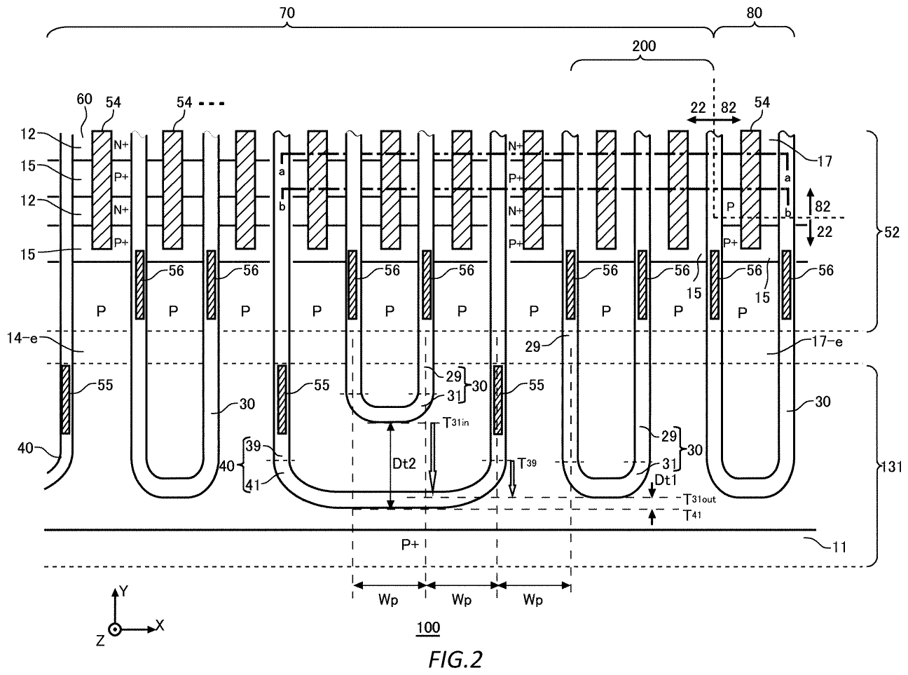

FIG. 2 is an enlarged view of a region D1 in FIG. 1. The region D1 is a region including the transistor section 70, the diode section 80, and the active-side gate runner 131. Although omitted in FIG. 1, a boundary region 200 is arranged in a region of the transistor section 70 which is in direct contact with the diode section 80 in the X axis direction. In this example, the boundary region 200 is a part of the transistor section 70, that is, the transistor section 70 has the boundary region 200. Instead of this, the boundary region 200 may be a part of the diode section 80. Note that in the following description, the transistor section 70, the diode section 80, and the boundary region 200 may be separately described as mutually different parts.

The semiconductor device 100 in this example includes a gate trench portion 40, a dummy trench portion 30, an interlayer insulating film, an outer circumferential well region 11, an emitter region 12, a base region 14, and a contact region 15 that are provided inside the semiconductor substrate 10 on the upper surface side. In addition, the semiconductor device 100 in this example includes an emitter electrode 52, the outer circumferential gate runner 130, and the active-side gate runner 131 that are provided above the upper surface of the semiconductor substrate 10. Note that the outer circumferential gate runner 130 is not included in the region D1 and is therefore not illustrated in FIG. 2. A detailed explanation of the outer circumferential gate runner 130 will be described below.

Each of the gate trench portion 40 and the dummy trench portion 30 is an example of the trench portion described above. A plurality of trench portions formed in the active section 160 of the semiconductor substrate 10 have the gate trench portion 40 and the dummy trench portion 30, extend in a predetermined trench extension direction, and are arranged at a predetermined pitch in a predetermined trench array direction. In FIG. 2, an example of the pitch is denoted by Wp. The pitch Wp may refer to an interval of a center line which extends in an extension direction of each of two trench portions adjacent in the trench array direction. Note that the trench extension direction and the trench array direction may be orthogonal to each other, and in the illustrated example, the trench extension direction is the Y axis direction, and the trench array direction is the X axis direction.

A plurality of trench portions are provided in each of the transistor section 70, the diode section 80, and the boundary region 200. More specifically, in the transistor section 70 in this example, one or more gate trench portions 40 and one or more dummy trench portions 30 are provided along the first direction. In the diode section 80 in this example, the plurality of dummy trench portions 30 are provided along the first direction. In the diode section 80 in this example, the gate trench portion 40 is not provided. In the boundary region 200 in this example, the plurality of dummy trench portions 30 are provided along the first direction. In the boundary region 200 in this example, the gate trench portion 40 is not provided.

In this example, the dummy trench portion 30 has extension parts 29 which extend in the trench extension direction and a connection part 31 which connects adjacent two of the extension parts 29. Similarly, the gate trench portion 40 has extension parts 39 which extend in the trench extension direction and a connection part 41 which connects adjacent two of the extension parts 39. As illustrated in FIG. 2, shapes of end portions in the Y axis direction in both the dummy trench portion 30 and the gate trench portion 40 are U-shaped in the top view. End portions of the two extension parts 29 and 39 in the Y axis direction are connected to each other by the curved connection parts 31 and 41, so that electric field strengths in the end portions of the extension parts 29 and 39 can be relaxed. Note that the semiconductor device 100 may additionally or alternatively include the straight shaped dummy trench portion 30 that does not have the connection part 31 and the straight shaped gate trench portion 40 that does not have the connection part 41.

In the transistor section 70, any of the plurality of dummy trench portions 30 arranged in the X axis direction is provided between the two extension parts 39 connected by the connection part 41 of the gate trench portion 40. In the transistor section 70, the rest of the plurality of dummy trench portion 30 arranged in the X axis direction are not provided between the two extension parts 39 connected by the connection part 41 of the gate trench portion 40. In other words, the dummy trench portion 30 in the transistor section 70 includes the dummy trench portion 30 provided on an inner side of the U-shaped gate trench portion 40 and the dummy trench portion 30 provided on an outer side of the U-shaped gate trench portion 40. Note that in the transistor section 70, on the inner side of the U-shaped gate trench portion 40, one or more U-shaped dummy trench portions 30 may be provided, one or more straight shaped dummy trench portions 30 may be provided, or a combination of these may be provided.

In the semiconductor device 100, a difference between the end portion of the gate trench portion 40 and the end portion of the dummy trench portion 30 in the trench extension direction is less than or equal to twice the pitch described above. This may refer to a state in which 90% or more of all the trench portions included the semiconductor device 100 satisfy the condition. More specifically, as an example, this may refer to a state in which all or 90% or more of the trench portions in which contact holes 55 and 56 are formed in an interlayer insulating film provided on the upper surface, which will be described below in detail, among all trench portions included in the semiconductor device 100 satisfy the condition. The difference may be less than or equal to the pitch described above. in FIG. 2, examples of the difference are denoted by Dt1 and Dt2.

Dt1 is an example of the difference between the end portion of the connection part 41 of the gate trench portion 40 in the trench extension direction and the end portion in the trench extension direction of the dummy trench portion 30 that is not provided between the two extension parts 39 connected by the connection part 41 of the gate trench portion 40. Dt1 is, for example, less than or equal to the pitch Wp described above. For example, in FIG. 2, in the gate trench portion 40 in which an end portion of the connection part 41 on a negative side in the Y axis direction is denoted by T₄₁ and the dummy trench portion 30 in which an end portion of the connection part 31 on the negative side in the Y axis direction is denoted by T₃₁ₒᵤₜ, the distance Dt1 between the end portion T₃₁ₒᵤₜ of the connection part 31 of the dummy trench portion 30 and the end portion T₄₁ of the connection part 41 of the gate trench portion 40 in the trench extension direction is less than or equal to the pitch Wp described above. Dt1 may be approximately 0. That is, in the gate trench portion 40 and the dummy trench portion 30 that is not provided between the two extension parts 39 connected by the connection part 41 of the gate trench portion 40, positions of the end portions in the Y axis direction are approximately the same, that is, the end portions in the Y axis direction may be aligned.

Dt2 is an example of the difference between the end portion of the gate trench portion 40 in the trench extension direction and the end portion in the trench extension direction of the dummy trench portion 30 provided between the two extension parts 39 connected by the connection part 41 of the gate trench portion 40. Dt2 is, for example, less than or equal to the pitch Wp described above. For example, in FIG. 2, in the gate trench portion 40 in which an end portion of the connection part 41 on the negative side in the Y axis direction is denoted by T₄₁ and the dummy trench portion 30 in which an end portion of the connection part 31 on the negative side in the Y axis direction is denoted by T₃₁ᵢₙ, the distance Dt2 in the trench extension direction between the end portion T₃₁ᵢₙ of the connection part 31 of the dummy trench portion 30 and the end portion T₄₁ of the connection part 41 of the gate trench portion 40 is less than or equal to the pitch Wp described above.

As an example, in the transistor section 70, on the inner side of the U-shaped gate trench portion 40, two U-shaped dummy trench portions 30 may be provided as a double structure. In this case too, a difference between an end portion in the trench extension direction of the innermost dummy trench portion 30 and an end portion in the trench extension direction of the outermost gate trench portion 40 is less than or equal to twice the pitch Wp described above. For example, in a middle dummy trench portion 30 positioned between the innermost dummy trench portion 30 and the outermost gate trench portion 40, an end portion in the trench extension direction may be spaced apart by one pitch from the end portion in the trench extension direction of the innermost dummy trench portion 30 and from the end portion in the trench extension direction of the outermost gate trench portion 40. Note that in this case, the contact region 15 may be formed in a mesa portion 60 between the two extension parts 29 in the innermost dummy trench portion 30 to facilitate hole extraction.

As an example, in the transistor section 70, on the inner side of the U-shaped gate trench portion 40, the straight shaped dummy trench portion 30 that does not have the connection part 31 may be provided. In this case too, a difference between an end portion of the straight shaped dummy trench portion 30 in the trench extension direction and the end portion of the gate trench portion 40 in the trench extension direction is less than or equal to twice the pitch Wp described above.

As an example, in the active section 160, the straight shaped dummy trench portion 30 that does not have the connection part 31 and the straight shaped gate trench portion 40 that does not have the connection part 41 may be provided. In this case too, a difference between the end portion of the straight shaped dummy trench portion 30 in the trench extension direction and an end portion of the straight shaped gate trench portion 40 in the trench extension direction is less than or equal to twice the pitch Wp described above.

In this example, the dummy trench portion 30 that is not provided between the two extension parts 39 connected by the connection part 41 of the gate trench portion 40 may be provided extending in the trench extension direction beyond the end portion of each of the extension parts 39 of the gate trench portion 40. For example, in FIG. 2, in the dummy trench portion 30 in which the end portion of the connection part 31 on the negative side in the Y axis direction is denoted by T₃₁ₒᵤₜ and the gate trench portion 40 in which the end portion of the extension part 39 on the negative side in the Y axis direction is denoted by T₃₉, the end portion T₃₁ₒᵤₜ of the connection part 31 of the dummy trench portion 30 is positioned on the negative side in the Y axis direction relative to the end portion T₃₉ of the extension part 39 of the gate trench portion 40.

In this example, the dummy trench portion 30 that is not provided between the two extension parts 39 connected by the connection part 41 of the gate trench portion 40 may be provided extending in the trench extension direction beyond the end portion in the trench extension direction of the dummy trench portion 30 provided between the two extension parts 39 connected by the connection part 41 of the gate trench portion 40. For example, in FIG. 2, in the dummy trench portion 30 in which the end portion of the connection part 31 on the negative side in the Y axis direction is denoted by T₃₁ₒᵤₜ and the dummy trench portion 30 in which the end portion of the connection part 31 on the negative side in the Y axis direction is denoted by T₃₁ᵢₙ, the end portion T₃₁ₒᵤₜ of the connection part 31 of the former dummy trench portion 30 is positioned on the negative side in the Y axis direction relative to the end portion T₃₁ᵢₙ of the connection part 31 of the latter dummy trench portion 30.

In this manner, according to the semiconductor device 100, by setting the difference between the end portion of the gate trench portion 40 and the end portion of the dummy trench portion 30 in the trench extension direction to be less than or equal to twice the pitch described above, a region where a trench density in the end portion of the active section 160 in the trench extension direction decreases is not to be provided. In the region where the trench density decreases, since a depletion layer hardly expands and a static breakdown voltage decreases, it is conceivable to cover the region with a deep diffusion layer of the P type. However, in the semiconductor device 100, without covering the region with the deep diffusion layer of the P type, that is, trench portions are provided to be spaced apart from the outer circumferential well region 11 to set the trench density in the end portion in the trench extension direction to be uniform, so that the decrease in the static breakdown voltage is avoided. With this configuration, the semiconductor device 100 can set an electric field in a trench end portion in the trench extension direction to be uniform and relax the electric field.

Any of a plurality of trench portions in the semiconductor device 100 are provided to be spaced apart from the outer circumferential well region 11. More specifically, the plurality of trench portions are provided to be spaced apart from the outer circumferential well region 11 in any directions of the trench extension direction and the trench array direction. At the end portion in the Y axis direction of each trench portion, a bottom portion of each trench portion in the depth direction is not covered with the outer circumferential well region 11. With this configuration, in the semiconductor device 100, a configuration can be adopted where a potential of the plurality of trench portions, that is, a potential of the active section 160 does not become a potential of the outer circumferential well region 11. In other words, in the semiconductor device 100, a potential in a part surrounded by the trench of the active section 160 can be set to a potential different from the potential of the outer circumferential well region 11, for example, to a floating potential, a degree of freedom in design can be improved.

The interlayer insulating film is provided above the semiconductor substrate 10, more specifically, provided between the emitter electrode 52, the outer circumferential gate runner 130, and the active-side gate runner 131 and the upper surface of the semiconductor substrate 10. In FIG. 2, illustration of the interlayer insulating film is omitted. In the interlayer insulating film in this example, contact holes 54, 55, and 56 are provided penetrating the interlayer insulating film. In FIG. 2, each of the contact holes 54, 55, and 56 is hatched with diagonal lines.

The emitter electrode 52 is formed of a material containing metal. For example, at least some region of the emitter electrode 52 is formed of aluminum or an alloy main component of which is aluminum, for example, a metal alloy such as AlSi or AlSiCu. The emitter electrode 52 may have a barrier metal formed of titanium, a titanium compound, or the like in a layer below a region formed of aluminum or the like. Further, a plug portion, which is formed by embedding tungsten or the like so as to be in contact with the barrier metal and aluminum or the like, may be included in the contact hole.

The emitter electrode 52 is provided above the gate trench portion 40, the dummy trench portion 30, the emitter region 12, the base region 14, and the contact region 15. The emitter electrode 52 is not provided above the outer circumferential well region 11. In FIG. 2, a range where the emitter electrode 52 is provided is indicated by a dashed line.

The emitter electrode 52 comes into contact with the emitter region 12, the contact region 15, and the base region 14 on the upper surface of the semiconductor substrate 10 through the contact hole 54 provided in the interlayer insulating film. The emitter electrode 52 is also connected to a dummy conductive portion in the dummy trench portion 30 through the contact hole 56 provided in the interlayer insulating film. In this example, the emitter electrode 52 is connected to the dummy conductive portion of the dummy trench portion 30 via the contact hole 56 provided in each of the two extension parts 29 of the dummy trench portion 30. In this manner, by providing two contact holes 56 in one dummy trench portion 30, a gate resistance can be reduced, and even when one of the two contact holes 56 suffers connection failure, another can be caused to continue to function. The emitter electrode 52 may be connected to the dummy conductive portion of the dummy trench portion 30 also in the connection part 31 at a leading edge of the dummy trench portion 30 in the Y axis direction. The dummy conductive portion of the dummy trench portion 30 is connected to the emitter electrode 52 and controlled to a potential of the emitter electrode 52.

The active-side gate runner 131 is provided above the gate trench portion 40, the dummy trench portion 30, and the outer circumferential well region 11. The active-side gate runner 131 is provided to be spaced apart from the emitter electrode 52. In FIG. 2, a range where the active-side gate runner 131 is provided is indicated by a dashed line.

The active-side gate runner 131 is connected to a gate conductive portion of the gate trench portion 40 via the contact hole 55 provided in the interlayer insulating film. In this example, the active-side gate runner 131 is connected to the gate conductive portion of the gate trench portion 40 via the contact hole 55 provided in each of the two extension parts 39 of the gate trench portion 40. In this manner, by providing two contact holes 55 to one gate trench portion 40, the gate resistance can be reduced, and even when one of the two contact holes 55 suffers connection failure, another can be caused to continue to function. The active-side gate runner 131 may be connected to a gate conductive portion of the gate trench portion 40 also in the connection part 41 at a leading edge of the gate trench portion 40 in the Y axis direction. The active-side gate runner 131 is not connected to the dummy conductive portion in the dummy trench portion 30.

The base region 14 is a region of the second conductivity type. The outer circumferential well region 11 is provided overlapping the outer circumferential gate runner 130 and the active-side gate runner 131. The outer circumferential well region 11 is provided extending with a predetermined width also in a range not overlapping the outer circumferential gate runner 130 and the active-side gate runner 131. In this example, the outer circumferential well region 11 is provided to be spaced apart from a plurality of trench portions of the active section 160. A configuration may be adopted where the outer circumferential well region 11 is not provided to be spaced apart from the plurality of trench portions of the active section 160. The outer circumferential well region 11 in this example is provided to be spaced apart from the plurality of trench portions of the active section 160 in any directions of the trench extension direction and the trench array direction. The outer circumferential well region 11 is a region of the second conductivity type having a higher doping concentration than that of the base region 14. The base region 14 in this example is of the P type, and the outer circumferential well region 11 is of the P+ type. A diffusion depth of the outer circumferential well region 11 may be deeper than depths of the gate trench portion 40 and the dummy trench portion 30.

The mesa portion 60 is provided between each trench portion in the first direction. The mesa portion 60 refers to a region sandwiched between the trench portions inside the semiconductor substrate 10. As an example, an upper edge of the mesa portion 60 is the upper surface of the semiconductor substrate 10. A depth position of a lower end of the mesa portion 60 is the same as a depth position of a lower end of the trench portion. The mesa portion 60 in this example is provided extending in the second direction (Y axis direction) along the trench on the upper surface of the semiconductor substrate 10. The mesa portion 60 of the transistor section 70, the mesa portion 60 of the diode section 80, and the mesa portion 60 of the boundary region 200 may have different structures

When the mesa portion 60 is simply mentioned in the present specification, this may refer to each of the mesa portion 60 of the transistor section 70, the mesa portion 60 of the diode section 80, and the mesa portion 60 of the boundary region 200.

The base region 14 described above is provided in the mesa portions 60 of the transistor section 70 and the boundary region 200. A doping concentration of the base region 14 of the boundary region 200 may be the same as, or may be different from, a doping concentration of the base region 14 of the transistor section 70. In the mesa portions 60 of the transistor section 70 and the boundary region 200, a region arranged closest to the active-side gate runner 131 in the base region 14 exposed on the upper surface of the semiconductor substrate 10 is set as a base region 14-e. While FIG. 2 illustrates the base region 14-e arranged in one end portion of each mesa portion 60 in the second direction, the base region 14-e is also arranged in another end portion of each mesa portion 60.

The mesa portion 60 of the transistor section 70 has the emitter region 12 of the first conductivity type which is exposed on the upper surface of the semiconductor substrate 10. The emitter region 12 is provided in contact with the gate trench portion 40. The mesa portion 60 in contact with the gate trench portion 40 may be provided with the contact region 15 of the second conductivity type which is exposed on the upper surface of the semiconductor substrate 10.

In the mesa portion 60 of the transistor section 70 in this example, the emitter region 12 and the contact region 15 are provided in a region sandwiched between the base regions 14-e in the top view. The contact region 15 is a region of the second conductivity type having a higher doping concentration than that of the base region 14. The emitter region 12 in this example is of the N+ type, and the contact region 15 is of the P+ type. The emitter region 12 and the contact region 15 may be provided between the base region 14 and the upper surface of the semiconductor substrate 10 in the depth direction.

Each of the emitter region 12 and the contact region 15 in the mesa portion 60 of the transistor section 70 is provided from one trench portion to another trench portion in the X axis direction. As an example, the emitter regions 12 and the contact regions 15 in the mesa portion 60 of the transistor section 70 are alternately arranged in the second direction (Y axis direction) of the trench portion. In another example, the contact regions 15 and the emitter regions 12 in the mesa portion 60 may be provided in stripes along the second direction (Y axis direction) of the trench portion. For example, the emitter region 12 is provided in a region in contact with the trench portion, and the contact region 15 is provided in a region sandwiched between the emitter regions 12.

The mesa portion 60 of the diode section 80 is not provided with the emitter region 12. The mesa portion 60 of the diode section 80 is provided with an anode region 17. The anode region 17 is a region of the second conductivity type. The anode region 17 in this example is of the P type. In the anode region 17 exposed on the upper surface of the semiconductor substrate 10 in the mesa portion 60 of the diode section 80, a region arranged closest to the active-side gate runner 131 is set as an anode region 17-e. While FIG. 2 illustrates the anode region 17-e arranged in one end portion in the second direction of the mesa portion 60 of the diode section 80, the anode region 17-e is also arranged in another end portion.

In the mesa portion 60 of the diode section 80, the contact region 15 described above may be provided in a region sandwiched between the anode regions 17-e in the top view, and the anode region 17 may be provided in a region sandwiched between the contact regions 15 in the top view. The anode region 17 may be arranged in an entire region sandwiched between the contact regions 15. The contact region 15 may be provided between the anode region 17 and the upper surface of the semiconductor substrate 10 in the depth direction. Note that a configuration may be adopted where in the mesa portion 60 of the diode section 80, the anode region 17 is provided on an entire surface in the region sandwiched between the anode regions 17-e in the top view, and the contact region 15 is not provided.

In the mesa portion 60 of the boundary region 200, the contact region 15 described above may be provided in the region sandwiched between the base regions 14-e in the top view. The mesa portion 60 of the boundary region 200 is not provided with the emitter region 12. The boundary region 200 may be a region where a channel is not formed in the mesa portion 60. The boundary region 200 may be a region where the channel is formed at a proportion lower than that of the transistor section 70.

The mesa portion 60 of the boundary region 200 may have a same structure as the mesa portion 60 of the diode section 80 or may have a different structure. In the mesa portion 60 of the boundary region 200 in this example, the contact region 15 is provided in the entire region that is sandwiched between the base regions 14-e. In other words, an area of the contact region 15 of the mesa portion 60 of the boundary region 200 may be greater than an area of the contact region 15 of the mesa portion 60 of the diode section 80. In this case, holes in the semiconductor substrate 10 can be easily extracted to the emitter electrode 52 via the mesa portion 60 of the boundary region 200.

In addition, in the mesa portion 60 of the boundary region 200, an impurity region of the N type may be provided which has a doping concentration approximately the same as that of the emitter region 12 or lower than that of the emitter region 12. Note that in that case, the boundary region 200 is not provided with the gate trench portion 40. In the following explanation, the impurity region may be referred to as an accumulation region.

A trench portion in a boundary position between the transistor section 70 and the boundary region 200 is the dummy trench portion 30. In the mesa portion 60 of the boundary region 200, the impurity region of the N type is not in contact with the gate trench portion 40, and therefore a current that is greater than that of the transistor section 70 does not flow into the boundary region 200. In this way, the injection of the holes from the mesa portion 60 of the boundary region 200 can be suppressed, and a reverse recovery loss can be reduced.

The contact hole 54 described above is provided above each of the mesa portions 60. The contact hole 54 is arranged in the region sandwiched between the base regions 14-e. The contact hole 54 in this example is provided above each region of the contact region 15, the base region 14, and the emitter region 12. The contact hole 54 is not provided in regions corresponding to the base region 14-e and the outer circumferential well region 11. The contact hole 54 may be arranged at a center of the mesa portion 60 in the first direction (X axis direction).

In the diode section 80, a cathode region 82 of the N+ type is provided in a region in direct contact with the lower surface of the semiconductor substrate 10. On the lower surface of the semiconductor substrate 10, a collector region 22 of the P+ type may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line. In addition, in the transistor section 70 and the boundary region 200, the collector region 22 of the P+ type is provided in the region in direct contact with the lower surface of the semiconductor substrate 10.

The cathode region 82 is arranged away from the outer circumferential well region 11 in the Y axis direction. With this configuration, a distance between the P type region (the outer circumferential well region 11) which comparatively has a high doping concentration and is formed up to a deep position and the cathode region 82 can be ensured, so that the breakdown voltage can be improved. The end portion of the cathode region 82 in the Y axis direction in this example is arranged farther away from the outer circumferential well region 11 than the end portion of the contact hole 54 in the Y axis direction. In another example, the end portion of the cathode region 82 in the Y axis direction may be arranged between the outer circumferential well region 11 and the contact hole 54.

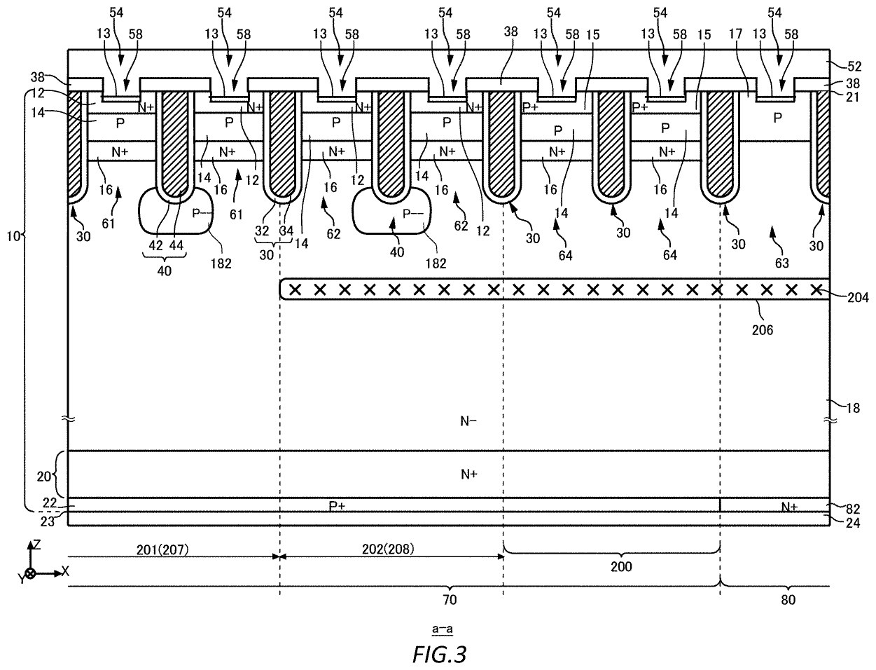

FIG. 3 illustrates an example of a cross section a-a in FIG. 2. The cross section a-a is an X-Z plane passing through the emitter region 12 and the cathode region 82. The semiconductor device 100 in this example includes the semiconductor substrate 10, the interlayer insulating film 38, the emitter electrode 52, and a collector electrode 24 in the cross section.

The interlayer insulating film 38 is provided on the upper surface of the semiconductor substrate 10. The interlayer insulating film 38 is a film including at least one layer of an insulating film such as silicate glass to which an impurity such as boron or phosphorous is added, a thermal oxide film, and other insulating films. In the cross section of FIG. 3, the contact hole 54 described with reference to FIG. 2 is provided in the interlayer insulating film 38.

The emitter electrode 52 is provided above the interlayer insulating film 38. The emitter electrode 52 is in contact with a front surface 21 of the semiconductor substrate 10 through the contact hole 54 of the interlayer insulating film 38. The collector electrode 24 is provided on the lower surface 23 of the semiconductor substrate 10. The emitter electrode 52 and the collector electrode 24 are formed of a metal material such as aluminum. In the present specification, the direction (Z axis direction) in which the emitter electrode 52 is connected to the collector electrode 24 is referred to as a depth direction. As described below in detail, the emitter electrode 52 may have a barrier metal containing titanium in a part in contact with the front surface 21 of the semiconductor substrate 10. The barrier metal may have a titanium nitride layer or may have a stacked structure of a titanium nitride layer and a titanium layer. As described below in detail, the emitter electrode 52 may have a plug portion made of tungsten with which the inside of the contact hole 54 is filled.

The semiconductor substrate 10 has a drift region 18 of the N type or the N− type, for example, of the first conductivity type. The drift region 18 in this example is a region of the N− type. The drift region 18 is provided in each of the transistor section 70, the diode section 80, and the boundary region 200. The base region 14 and the contact region 15 are provided above the drift region 18.

The semiconductor substrate 10 also has the accumulation region 16 of the N type or the N+ type, for example, of the first conductivity type. The accumulation region 16 and the emitter region 12 described above are regions of the first conductivity type which have a doping concentration higher than that of the drift region 18. Both the accumulation region 16 and the emitter region 12 in this example are regions of the N+ type.

The accumulation region 16 accumulates holes below the accumulation region 16. Providing the accumulation region 16 having a high concentration between the drift region 18 and the base region 14 can increase a carrier injection enhancement effect (IE effect) and reduce an on-voltage. The doping concentration of the accumulation region 16 may be ten times or more, may be fifty times or more, or may be a hundred times or more, higher than the doping concentration of the drift region 18.

The transistor section 70 has a first transistor region 201 including the emitter region 12 and the gate trench portion 40, and a second transistor region 202 including the emitter region 12 and the gate trench portion 40. The second transistor region 202 is provided between the first transistor region 201 and the diode section 80.

As described above, the transistor section 70 has the boundary region 200 provided to be adjacent to the diode section 80 rather than the second transistor region 202. As an example, the accumulation region 16 is provided in the mesa portion 60 of the first transistor region 201, the mesa portion 60 of the second transistor region 202, and the mesa portion 60 of the boundary region 200. The accumulation region 16 is not provided in the mesa portion 60 of the diode section 80.

In this example, the front surface of the semiconductor substrate 10 in the boundary region 200 where the accumulation region 16 is provided in the mesa portion 60 is the contact region 15. When the front surface of the semiconductor substrate 10 in the boundary region 200 is set as the contact region 15, hole injection increases, but hole injection can be suppressed in the accumulation region 16 of the mesa portion 60 of the boundary region 200.

In this example, a plurality of the mesa portions 60 include one or more first mesa portions 61, one or more second mesa portions 62, one or more third mesa portions 63, and one or more fourth mesa portions 64. The first mesa portion 61 and the second mesa portion 62 are provided in the transistor section 70. More specifically, the first mesa portion 61 is provided in the first transistor region 201, and the second mesa portion 62 is provided in the second transistor region 202. That is, the second mesa portion 62 is arranged between the first mesa portion 61 and the diode section 80. The third mesa portion 63 is provided in the diode section 80, and the fourth mesa portion 64 is provided in the boundary region 200.

In the first mesa portion 61 of the first transistor region 201 and the second mesa portion 62 of the second transistor region 202, the emitter region 12 of the N+ type and the base region 14 of the P type are provided in the stated order from the front surface 21 side of the semiconductor substrate 10.

The emitter region 12 is exposed on the front surface 21 of the semiconductor substrate 10 and is provided in contact with the gate trench portion 40. The emitter region 12 may be in contact with the trench portions on both sides of the mesa portion 60.

In the transistor section 70, the base region 14 is provided below the emitter region 12. The base region 14 in the transistor section 70 in this example is provided in contact with the emitter region 12. In the transistor section 70, the base region 14 may be in contact with the trench portions on both sides of the first mesa portion 61 and the second mesa portion 62.

The third mesa portion 63 of the diode section 80 has the anode region 17 of the second conductivity type which is provided above the drift region 18. The anode region 17 in the diode section 80 is in contact with the front surface 21 of the semiconductor substrate 10. A doping concentration of the anode region 17 of the second conductivity type may be the same as, or may be different from, a doping concentration of the base region 14 of the second conductivity type.

A doping concentration of the anode region 17 of the second conductivity type in the diode section 80 may be greater than, may be less than, or may be the same as, the doping concentration of the base region 14 in the transistor section 70. The doping concentration of the anode region 17 may be greater than, may be less than, or may be the same as, the doping concentration of the base region 14 in the boundary region 200. As an example, the doping concentration of the anode region 17 of the second conductivity type in the diode section 80 is greater than or equal to the doping concentration of the base region 14 in the transistor section 70 and the boundary region 200.

In the fourth mesa portion 64 of the boundary region 200 in this example, the contact region 15 of the P+ type is provided in contact with the front surface 21 of the semiconductor substrate 10. In addition, in the fourth mesa portion 64, the base region 14 is provided between the contact region 15 and the drift region 18.

In the first mesa portion 61, the second mesa portion 62, the third mesa portion 63, and the fourth mesa portion 64, a trench contact portion 58 is provided extending in the depth direction of the semiconductor substrate 10 from the front surface 21 of the semiconductor substrate 10. The trench contact portion 58 is a part in which a metal electrode such as the emitter electrode 52 is provided inside the semiconductor substrate 10. The trench contact portion 58 can be formed by forming a groove on the front surface 21 of the semiconductor substrate 10 exposed by the contact hole 54 and filling an inside of the groove with the metal electrode. A region where the first mesa portion 61 or the like is in contact with the metal electrode such as the emitter electrode 52 is equivalent to a contact portion. In the first mesa portion 61 or the like, a plug region 13 which will be described below in detail may be provided in a region in contact with a lower end of the contact portion. The plug region 13 in this example is provided below the trench contact portion 58. The plug region 13 in this example is in contact with a bottom surface of the trench contact portion 58. Note that a configuration may be adopted where the trench contact portion 58 is not provided in the first mesa portion 61, the second mesa portion 62, the third mesa portion 63, and the fourth mesa portion 64, and an upper surface of the mesa portion 60 may be set as a simple contact portion.

Widths of the trench contact portions 58 in the depth direction in this example are uniform in all of the first mesa portion 61, the second mesa portion 62, the third mesa portion 63, and the fourth mesa portion 64, but may be different from each other. For example, the trench contact portion 58 and the contact region 15 of the second mesa portion 62 may be deeper towards the drift region 18 than the trench contact portion 58 and the contact region 15 of the first mesa portion 61.

In each of the transistor section 70, the diode section 80, and the boundary region 200, the N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in this example may have two or more concentration peaks in the depth direction (Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor section 70, the collector region 22 of the P+ type is provided below the buffer region 20. An acceptor concentration of the collector region 22 is higher than an acceptor concentration of the base region 14. The collector region 22 may include an acceptor which is the same as or may include different from an acceptor of the base region 14. The acceptor of the collector region 22 is, for example, boron.

Below the buffer region 20 in the diode section 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

In the boundary region 200, the collector region 22 of the P+ type is provided below the buffer region 20. The collector region 22 of the boundary region 200 may have the same doping concentration as the collector region 22 of the transistor section 70. The boundary position between the cathode region 82 and the collector region 22 in the X axis direction may be set as a boundary position between the diode section 80 and the boundary region 200 in the X axis direction.

In another example, in the boundary region 200, a part or all of the collector regions 22 may be replaced with the cathode region 82. When the cathode region 82 is provided on a lower surface of the boundary region 200, a region where the contact regions 15 and the anode regions 17 are alternately arranged in the region sandwiched between the anode regions 17-e may be set as the diode section 80, and a region where the contact region 15 is arranged in the entire region sandwiched between the base regions 14-e may be set as the boundary region 200. When the cathode region 82 is provided on the lower surface of the boundary region 200, the boundary region 200 may be considered as a part of the diode section 80.

Among the trench portions adjacent to the mesa portion in which the channel is formed, the trench portion arranged closest to the diode section 80 in the X axis direction may be set as a boundary position between the transistor section 70 and the boundary region 200 or the diode section 80 in the X axis direction. Of the two trench portions in contact with the emitter region 12 arranged closest to the diode section 80 in the X axis direction, the trench portion on the diode section 80 side may be the dummy trench portion 30. The dummy trench portion 30 in this case may be set as the boundary position between the transistor section 70 and the boundary region 200 or the diode section 80 in the X axis direction.

The boundary region 200 may be provided with the emitter region 12. Note that in that case, the boundary region 200 is not provided with the gate trench portion 40. Moreover, the trench portion in the boundary position between the transistor section 70 and the boundary region 200 is the dummy trench portion 30. That is, transistor operations do not occur in the boundary region 200. The boundary region 200 may be provided with the gate trench portion 40. Note that in that case, the boundary region 200 is not provided with the emitter region 12, or even when the boundary region 200 is provided with the emitter region 12, the emitter region 12 is not in contact with the gate trench portion 40. That is, transistor operations do not occur in the boundary region 200.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10.

One or more gate trench portions 40 and one or more dummy trench portions 30 are provided on the front surface 21 side of the semiconductor substrate 10. Each trench portion is provided penetrating the base region 14 from the front surface 21 of the semiconductor substrate 10 up to a position below the base region 14 (until reaching the drift region 18). In a region where at least any of the emitter region 12 or a contact region 15 is provided, each trench portion also penetrates these doping regions. A configuration in which a trench portion penetrates a doping region is not limited to a configuration which is manufactured by forming a doping region and forming a trench portion in this order. The configuration of the trench portions penetrating the doping region also includes a configuration of forming the trench portions and then forming the doping region between the trench portions.

As described above, the transistor section 70 is provided with the gate trench portion 40 and the dummy trench portion 30. The diode section 80 and the boundary region 200 in this example are provided with the dummy trench portion 30 and are not provided with the gate trench portion 40. Note that the gate trench portion 40 may be arranged or the dummy trench portion 30 may be arranged at the boundary between the boundary region 200 and the transistor section 70.

Note that the boundary region 200 is a buffering structure for arranging different structures of the transistor section 70 and the diode section 80 side by side. Therefore, the width of the boundary region 200 in the X axis direction may be short. For example, in the boundary region 200, one or more fourth mesa portions 64 may be provided, and the boundary region 200 may not be provided.

The boundary region 200 may include a plurality of fourth mesa portions 64 in the X axis direction. This allows the effects of the transistor section 70 on the characteristics of the diode section 80, for example, the effects of the operation of the gate trench portion 40 and the discharge or injection of holes in the contact region 15, on the forward voltage and reverse recovery characteristics, to be suppressed. The number of mesa portions refers to the number of mesa portions arranged side by side in the X axis direction.

The gate trench portion 40 has a gate trench, a gate insulating film 42, and a gate conductive portion 44 that are provided on the front surface 21 of the semiconductor substrate 10. The gate insulating film 42 is provided covering the inner wall of the gate trench. The gate insulating film 42 may be formed by oxidizing or nitriding a semiconductor in the inner wall of the gate trench. Inside the gate trench, the gate conductive portion 44 is provided on an inner side relative to the gate insulating film 42. In other words, the gate insulating film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered with the interlayer insulating film 38 on the front surface 21 of the semiconductor substrate 10 other than a place where the contact hole 55 is formed. The gate conductive portion 44 is electrically connected to the gate runner via the contact hole 55. When a predetermined gate voltage is applied to the gate conductive portion 44, a channel is formed by an electron inversion layer in a surface layer of the base region 14 at a boundary in contact with the gate trench portion 40.

Herein, the semiconductor substrate 10 includes trench bottom regions 182 of the second conductivity type which are provided in contact with lower ends of a plurality of trench portions. The trench bottom region 182 has a doping concentration lower than that of the base region 14 of the second conductivity type. The trench bottom region 182 in this example is of the P−− type as an example. The doping concentration of the trench bottom region 182 may be greater than or equal to 1% or less than or equal to 10% of the doping concentration of the base region 14. In the trench array direction, the trench bottom region 182 may be provided such that its leading edge is in contact with an adjacent trench portion.

In this example, the trench bottom region 182 is provided in contact with the lower end of the gate trench portion 40. By providing the trench bottom region 182 in contact with the lower end of the gate trench portion 40, a gate-collector capacitance can be increased, and dV/dt at the time of switching can be reduced. With this configuration, since it is possible to reduce the gate resistance in a case of such a design that dV/dt becomes a same value, dl/dt can be increased, and a switching loss of the semiconductor device 100 can be reduced.

The dummy trench portions 30 may have the same structure as the gate trench portions 40 in the cross section. The dummy trench portion 30 has a dummy trench, a dummy insulating film 32, and a dummy conductive portion 34 that are provided on the front surface 21 of the semiconductor substrate 10. The dummy insulating film 32 is provided covering an inner wall of the dummy trench. The dummy conductive portion 34 is provided inside the dummy trench and is provided on an inner side relative to the dummy insulating film 32. The dummy insulating film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like.

The dummy conductive portion 34 may have the same length in the depth direction as the gate conductive portion 44. The dummy trench portion 30 in the cross section is covered with the interlayer insulating film 38 on the front surface 21 of the semiconductor substrate 10 other than a place where the contact hole 56 is formed. The dummy conductive portion 34 is electrically connected to the emitter electrode 52 via the contact hole 56. Note that bottom portions of the dummy trench portion 30 and the gate trench portion 40 may be formed in a curved-surface shape (curved-line shape in the cross section) that is convex downward.

The semiconductor device 100 of this example includes a lifetime control region 206 provided on the front surface side relative to the center of the semiconductor substrate 10 in the depth direction of the semiconductor substrate 10. The lifetime control region 206 includes a lifetime killer which adjusts a lifetime of carriers. The lifetime control region 206 decreases a threshold voltage and also decreases the switching loss of the semiconductor device 100.

The lifetime control region 206 in this example is a region where a lifetime of charge carriers is locally short. The charge carriers are electrons or holes. The charge carriers may be simply referred to as carriers. The lifetime control region 206 in this example is formed through injection of charged particles such as helium ions from the front surface 21 side of the semiconductor substrate 10. In this example, a concentration distribution of helium or the like of the semiconductor substrate 10 in the depth direction may have such a shape that draws a hem from the lifetime control region 206 to the front surface 21 of the semiconductor substrate 10. In other words, the concentration (/cm³) of helium or the like may monotonically decrease from the lifetime control region 206 to the front surface 21.

The concentration of helium or the like in the front surface 21 may be greater than 0. On the other hand, also in a direction towards the lower surface 23 from the lifetime control region 206, the concentration of helium or the like may have such a shape that draws a hem. Note that the concentration of helium or the like more steeply decreases in the hem towards the lower surface 23 than that in the hem towards the front surface 21. The concentration of helium or the like in the lower surface 23 is lower than the concentration of helium or the like in the front surface 21. The concentration of helium or the like in the front surface 21 may be less than or equal to a measurement limit or may be 0. Note that the lifetime control region 206 may be formed through injection of charged particles such as helium ions from the lower surface 23 side of the semiconductor substrate 10.

By injecting charged particles such as helium ions into the semiconductor substrate 10, lattice defects 204 such as vacancies are formed in a vicinity of the injection position. The lattice defects 204 generate recombination centers. The lattice defects 204 may be mainly composed of vacancies such as monovacancies (V) or divacancies (VV), may be dislocations, may be interstitial atoms, or may be transition metals or the like. For example, atoms adjacent to the vacancies have dangling bonds. In a broad sense, the lattice defects 204 may also include donors and acceptors, but in the present specification, the lattice defects 204 mainly composed of vacancies may be referred to as vacancy-type lattice defects, vacancy-type defects, or simply lattice defects. In the present specification, the lattice defects 204 may be simply referred to as recombination centers or lifetime killers as recombination centers contributing to recombination of carriers.

The lifetime killer may be formed through injection of helium ions to the semiconductor substrate 10. A helium chemical concentration may be set as a density of the lattice defect 204. Note that since the lifetime killer formed by injecting helium ions may be terminated by hydrogen existing in the buffer region 20, the depth position of the density peak of the lifetime killer may not be identical to the depth position of the helium chemical concentration peak. In addition, when injecting hydrogen ions into the semiconductor substrate 10, the lifetime killer may be formed in a passed-through region of hydrogen ions that is more on the injection surface side than the projected range.

The lattice defect 204 is an example of the lifetime killer. In FIG. 3, the lattice defects 204 at the injection positions of the charged particles are schematically indicated by X marks. In a region where many lattice defects 204 remain, the carriers are captured by the lattice defects 204, and thus the lifetime of the carriers is shortened. By adjusting the lifetime of carriers, characteristics of the diode section 80 such as a reverse recovery time and a reverse recovery loss can be adjusted. In the depth direction of the semiconductor substrate 10, a position where the carrier lifetime shows a local minimum may be set as a depth position of the lifetime control region 206.

The lifetime control region 206 is arranged on the front surface 21 side of the semiconductor substrate 10. The front surface 21 side is a region from the center position of the semiconductor substrate 10 in the depth direction to the front surface 21 of the semiconductor substrate 10. The lifetime control region 206 in this example is arranged below the lower end of the trench portion.

In a case where the lifetime control region 206 is formed through irradiation of highly penetrating particle beams such as electron beams, lattice defects are formed in a substantially uniform manner from the front surface 21 to the lower surface 23 of the semiconductor substrate 10. At this time too, the depth position of the lifetime control region 206 may be regarded as being arranged on the front surface 21 side of the semiconductor substrate 10.

The lifetime control region 206 extends from the diode section 80 to the second transistor region 202. When the semiconductor device 100 has the boundary region 200, the lifetime control region 206 is also provided in the boundary region 200. The lifetime control region 206 may be provided on the entire diode section 80 in the X axis direction. The lifetime control region 206 is also provided in the entire boundary region 200.

The lifetime control region 206 of the diode section 80 and the lifetime control region 206 of the transistor section 70 are provided in the same depth positions. In the transistor section 70, the second transistor region 202 may be an adjustment region 208 in which the lifetime control region 206 is provided, and the first transistor region 201 may be a non-adjustment region 207 in which the lifetime control region 206 is not provided.

Herein, a configuration may be adopted in which a boundary between the adjustment region 208 and the non-adjustment region 207 is not identical to a boundary between the first transistor region 201 and the second transistor region 202, and for example, the lattice defect 204 (the lifetime control region 206) may be provided from the second transistor region 202 to a part of the first transistor region 201.

The adjustment region 208 is a region overlapping the lifetime control region 206 in the top view. The non-adjustment region 207 is a region that is not overlapping the lifetime control region 206 in the top view. The non-adjustment region 207 is a region where the carrier lifetime in the same depth position as the lifetime control region 206 is longer than the carrier lifetime of the lifetime control region 206 of the diode section 80. The non-adjustment region 207 may be a region to which charged particles such as helium ions for forming the lifetime killer such as the lattice defect 204 are not injected. A chemical concentration (/cm³) of helium or the like in the non-adjustment region 207 may be the same as a chemical concentration of the charged particles at a center of the drift region 18 in the Z axis direction.

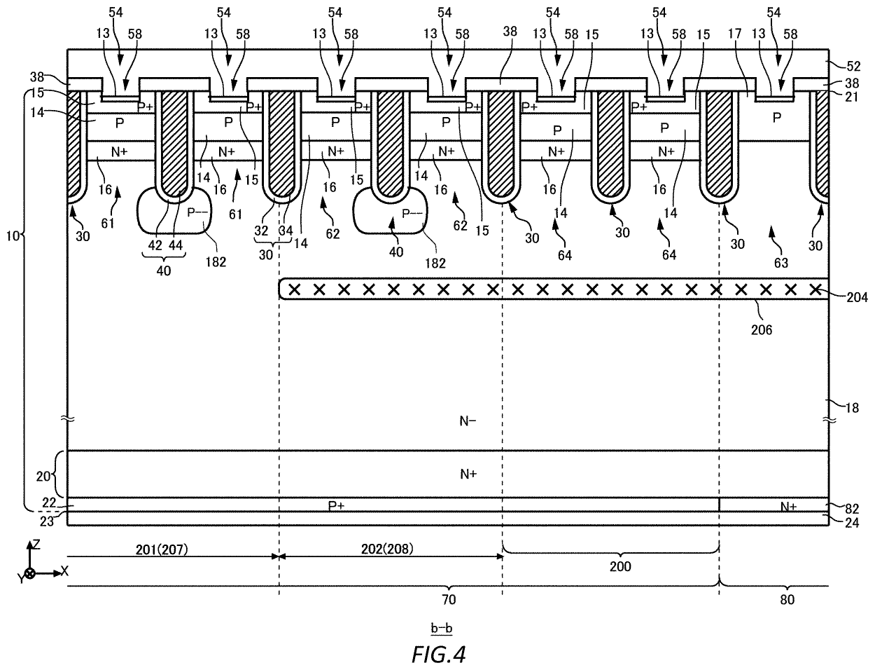

FIG. 4 illustrates an example of a cross section b-b in FIG. 2. The cross section b-b is an X-Z plane passing through the contact region 15 and the cathode region 82. The cross section in this example has a structure in which the emitter region 12 in the example illustrated in FIG. 3 is replaced with the contact region 15. A structure other than the contact region 15 is similar to that in FIG. 3.

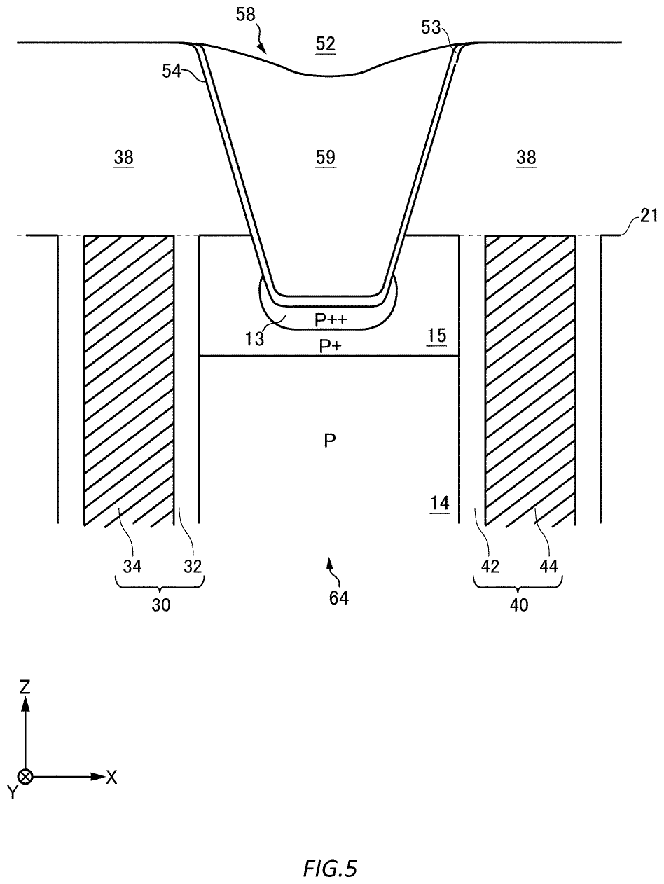

FIG. 5 is an enlarged view of an area in a vicinity of the trench contact portion 58 in the boundary region 200. In the fourth mesa portion 64 of the boundary region 200, a barrier metal 53 is provided on a side wall and a bottom surface of the contact hole 54. The barrier metal 53 may be provided on an entire bottom surface of the contact hole 54. A material of the barrier metal 53 may be titanium or a titanium compound. When the semiconductor substrate 10 is silicon, the barrier metal 53 may react with the semiconductor substrate 10 to form a silicide.

In the contact hole 54, a plug portion 59 is provided on an inner side of the barrier metal 53. A material of the plug portion 59 may be tungsten. The material of the plug portion 59 may be the same material as the emitter electrode 52. The barrier metal 53 and the plug portion 59 are also similarly provided in each of the contact holes 54 of the transistor section 70 and the diode section 80.

In at least a part of the mesa portion 60, the plug region 13 may be provided in a region in contact with the lower end of the contact portion. The plug region 13 is a region which is provided above the drift region 18 and has a doping concentration higher than that of the base region 14. The plug region 13 in this example is provided below the trench contact portion 58. The plug region 13 in this example is in contact with the bottom surface of the trench contact portion 58. The plug region 13 may be in contact with a side wall of the trench contact portion 58. The plug region 13 is a region of the second conductivity type which has a doping concentration higher than that of the base region 14. The plug region 13 in this example has a doping concentration higher than that of the contact region 15. The plug region 13 in this example is a region of the P++ type.

The plug region 13 may be provided extending in the trench extension direction on the bottom surface of the trench contact portion 58. The plug region 13 may be provided on an entire bottom surface of the trench contact portion 58. By providing each plug region 13, the holes can be easily extracted in each mesa portion 60. Thus, it is possible to suppress reduction in withstand capability.

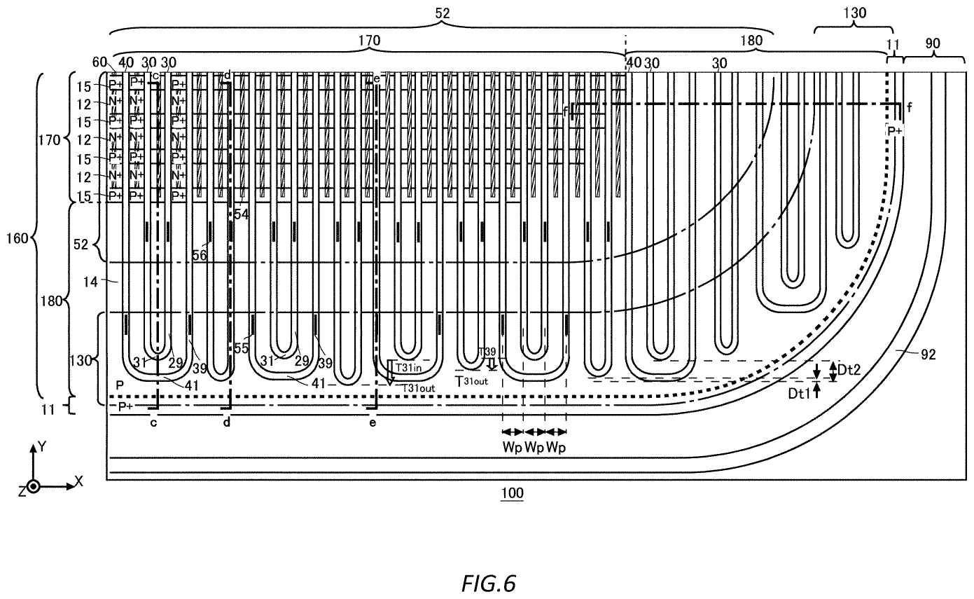

FIG. 6 is an enlarged view of the region D2 in FIG. 1. The region D2 is a region including the transistor section 70. In FIG. 6 and each of subsequent diagrams related to the region D2, it is regarded that each component such as the transistor section 70 included in the region D2 has been already described with reference to FIG. 1 to FIG. 5, and the duplicated description will be omitted.

In FIG. 6, the edge termination structure portion 90 is provided with a guard ring 92. The edge termination structure portion 90 may be provided with a plurality of guard rings 92. An impurity concentration of the guard ring 92 may be the same as that of the outer circumferential well region 11.

The active section 160 has a center portion 170 and an outer circumferential portion 180. The center portion 170 has the emitter region 12. The outer circumferential portion 180 surrounds the center portion 170. In this example, the outer circumferential portion 180 surrounds the center portion 170 in the top view. A boundary between the center portion 170 and the outer circumferential portion 180 may be set as the emitter region 12 closest to the outer circumferential well region 11 in the X axis direction or the Y axis direction.

The contact hole 54 is provided above each of the mesa portions 60 of the center portion 170. The contact hole 54 in this example is provided above each region of the contact region 15 and the emitter region 12. The contact hole 54 may be arranged at the center of the mesa portion 60 in the array direction (X axis direction).

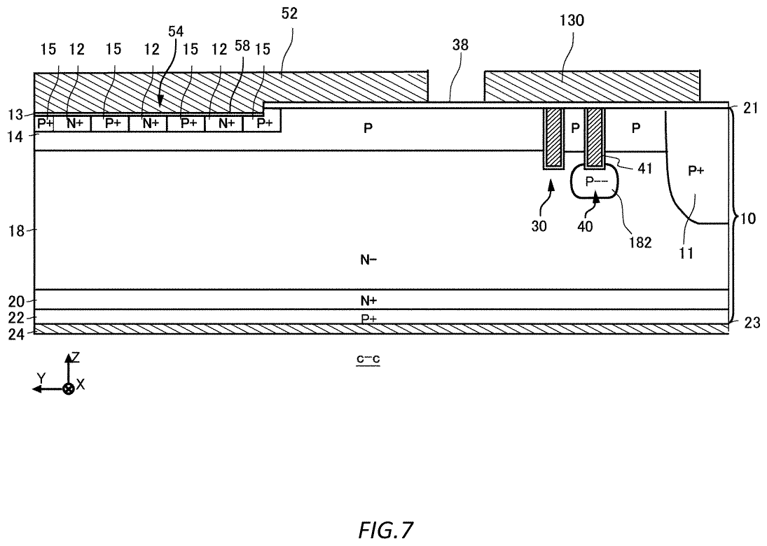

FIG. 7 illustrates an example of a cross section c-c in FIG. 6. The cross section c-c is a Y-Z plane passing through the connection part 41 of the gate trench portion 40 and the connection part 31 of the dummy trench portion 30. As illustrated in FIG. 7, the trench bottom region 182 is provided in contact with the lower end of the gate trench portion 40 in the connection part 41 of the gate trench portion 40. The trench bottom region 182 is spaced apart from the outer circumferential well region 11. An interval between the trench bottom region 182 and the outer circumferential well region 11 in the trench extension direction, that is, the Y axis direction, is greater than or equal to 4 μm and less than or equal to 14 μm, for example. When the interval is less than 4 μm, there is a risk that the trench bottom region 182 may come into contact with the outer circumferential well region 11, and when the interval is greater than 14 μm, there is a risk that the static breakdown voltage may decrease in the trench end portion of the semiconductor device 100.

In the cross section, the emitter electrode 52 comes into contact with the emitter region 12 and the contact region 15 on the upper surface of the semiconductor substrate 10 through the contact hole 54 provided in the interlayer insulating film. In the cross section, the outer circumferential gate runner 130 is provided above the gate trench portion 40, the dummy trench portion 30, and the outer circumferential well region 11. The outer circumferential gate runner 130 is provided to be spaced apart from the emitter electrode 52.

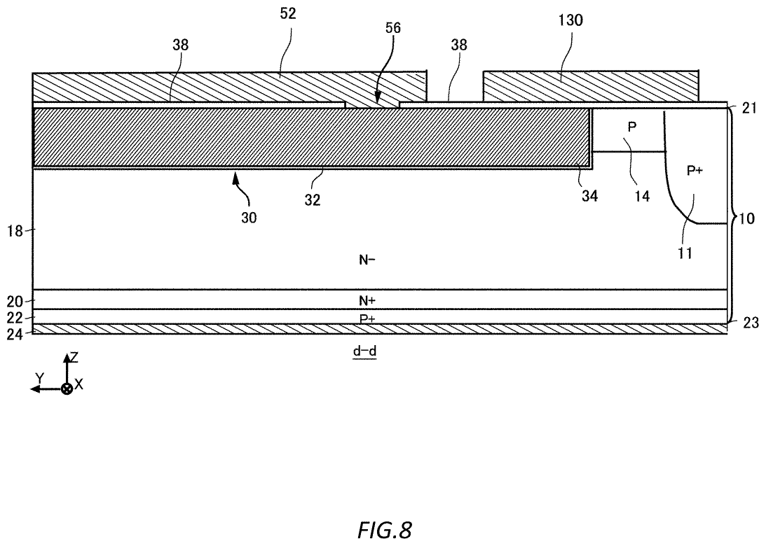

FIG. 8 illustrates an example of a cross section d-d in FIG. 6. The cross section d-d is a Y-Z plane passing through the extension part 29 of the dummy trench portion 30. The emitter electrode 52 is connected to the dummy conductive portion 34 in the dummy trench portion 30 through the contact hole 56 provided in the interlayer insulating film. In this example, the emitter electrode 52 is connected to the dummy conductive portion 34 of the dummy trench portion 30 via the contact hole 56 provided in each of the two extension parts 29 of the dummy trench portion 30. The dummy conductive portion 34 of the dummy trench portion 30 is connected to the emitter electrode 52 and controlled to a potential of the emitter electrode 52. In the cross section, the outer circumferential gate runner 130 is provided above the dummy trench portion 30 and the outer circumferential well region 11. The outer circumferential gate runner 130 is provided to be spaced apart from the emitter electrode 52.

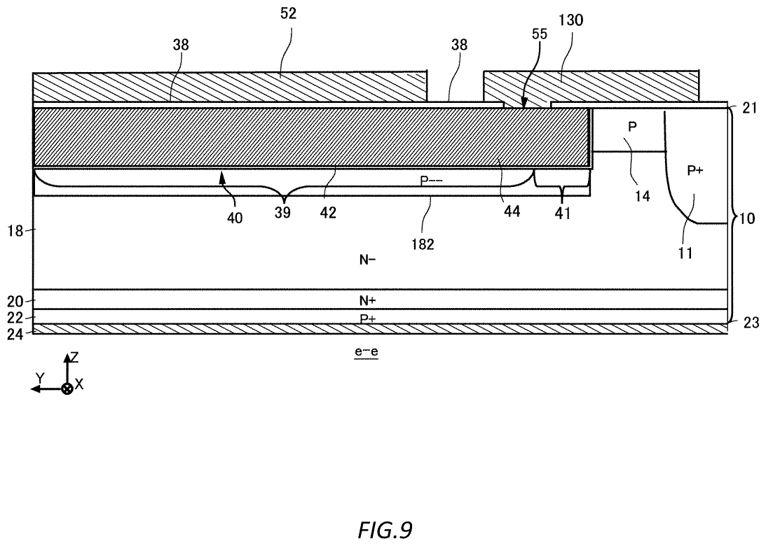

FIG. 9 illustrates an example of a cross section e-e in FIG. 6. The cross section e-e is a Y-Z plane passing through the extension part 39 of the gate trench portion 40. As may be appreciated from FIG. 6 and FIG. 9, the trench bottom region 182 may be provided extending on an outer side relative to the plurality of contact regions 15 in the trench extension direction. The trench bottom regions 182 may be provided over entire bottom portions of the extension part 39 and the connection part 41 of the gate trench portion 40. The trench bottom region 182 may be provided below the emitter region 12. The trench bottom region 182 may be provided, or may not be provided, below the contact region 15. The trench bottom region 182 in this example is also provided below the contact region 15.

The trench bottom region 182 may cover the emitter region 12 provided in contact with the gate trench portion 40 in the top view. The trench bottom region 182 in this example is provided extending in the extension direction in the mesa portion 60 adjacent to the gate trench portion 40 and covers the emitter region 12 provided in contact with the gate trench portion 40 in the top view. In the emitter region 12 provided in contact with the gate trench portion 40, a channel is formed when the semiconductor device 100 operates. In the top view, the trench bottom region 182 covers the emitter region 12 provided in contact with the gate trench portion 40, that is, the trench bottom region 182 is provided below the emitter region 12 provided in contact with the gate trench portion 40, so that occurrence of avalanche breakdown can be suppressed in the region where the channel is formed. With this configuration, a fluctuation of a threshold voltage Vth of the semiconductor device 100 can be suppressed.

In the cross section, the outer circumferential gate runner 130 is provided above the gate trench portion 40 and the outer circumferential well region 11. The outer circumferential gate runner 130 is provided to be spaced apart from the emitter electrode 52.

The outer circumferential gate runner 130 is connected to the gate conductive portion 44 of the gate trench portion 40 via the contact hole 55 provided in the interlayer insulating film. In this example, the outer circumferential gate runner 130 is connected to the gate conductive portion 44 of the gate trench portion 40 via the contact hole 55 provided in each of the two extension parts 39 of the gate trench portion 40.

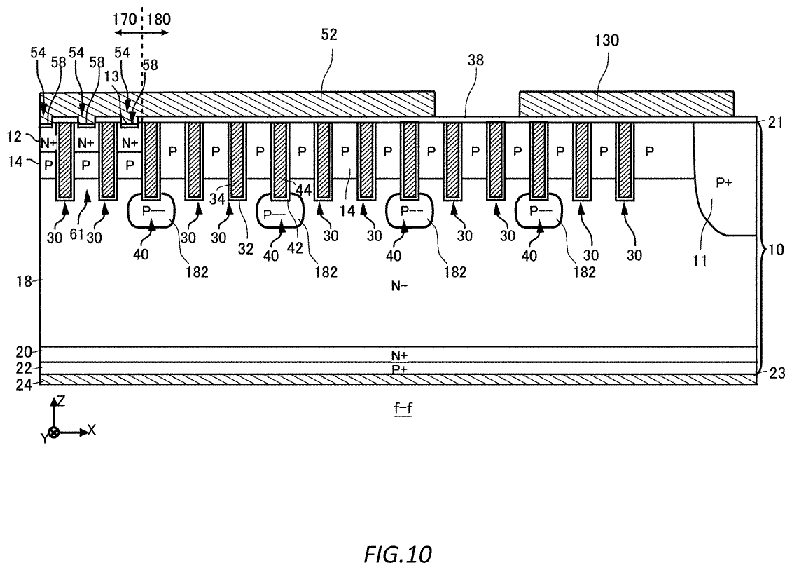

FIG. 10 illustrates an example of a cross section f-f in FIG. 6. The cross section f-f is an X-Z plane passing through the emitter region 12 of the center portion 170. In the outer circumferential portion 180, the emitter region 12 is not formed. In the outer circumferential portion 180 in this example, the contact region 15 is also not formed. The base region 14 is formed in each of the mesa portions 60 of the outer circumferential portion 180. Each of the mesa portions 60 of the outer circumferential portion 180 is not provided with the contact hole 54 and becomes a floating region.

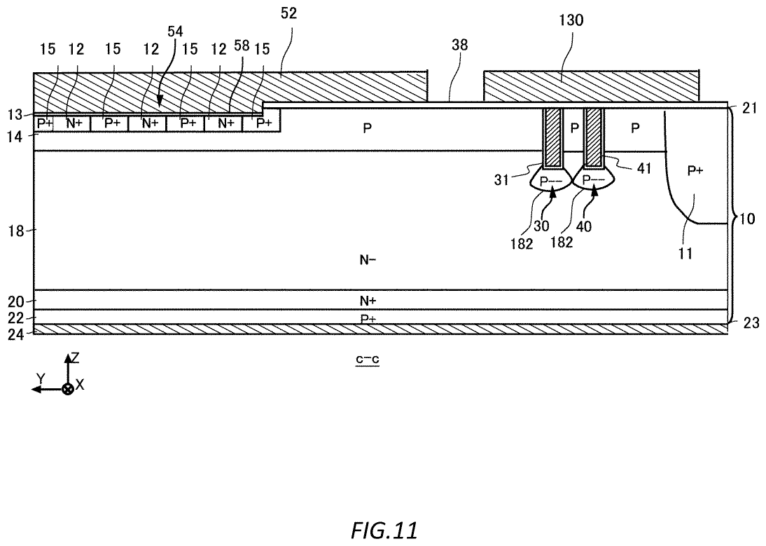

FIG. 11 illustrates another example of the cross section c-c in FIG. 6. The trench bottom region 182 may be provided in contact with also the lower end of the dummy trench portion 30 or may not be provided in contact with the lower end of the dummy trench portion 30. The trench bottom region 182 in this example is provided in contact with also the lower end of the dummy trench portion 30. The trench bottom region 182 in this example may be provided in contact with also the lower end of the end portion in the trench extension direction, that is, the lower end of the connection part 31, of the dummy trench portion 30 provided between the two extension parts 39 connected by the connection part 41 of the gate trench portion 40.

When a collector-emitter voltage of the semiconductor device 100 increases, an electric field in the bottom portion of the gate trench portion 40 may become stronger, and the avalanche breakdown may occur. When the avalanche breakdown occurs in the bottom portion of the gate trench portion 40, there is a risk that charges generated by the avalanche breakdown may be trapped in a gate insulating film, and the threshold voltage Vth of the semiconductor device 100 may fluctuate. By providing the trench bottom region 182 below the gate trench portion 40 and providing the trench bottom region 182 below the dummy trench portion 30 in part, the avalanche breakdown can be caused to preferentially occur in a region where the trench bottom region 182 is not formed in the bottom portion of the dummy trench portion 30. With this configuration, the occurrence of the avalanche breakdown in the bottom portion of the gate trench portion 40 can be suppressed, and the fluctuation of the threshold voltage Vth of the semiconductor device 100 can be suppressed.

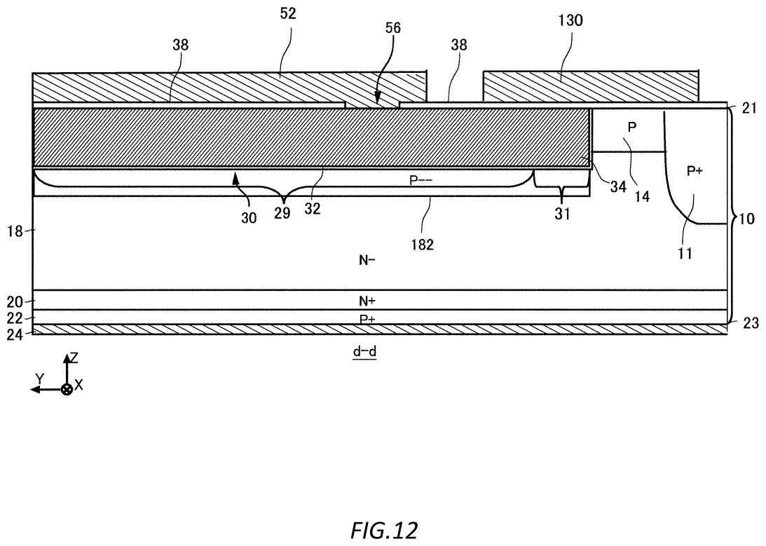

FIG. 12 illustrates another example of the cross section d-d in FIG. 6. The trench bottom region 182 may be provided in contact with also the lower end of the end portion in the trench extension direction, that is, the lower end of the connection part 31, of the dummy trench portion 30 that is not provided between the two extension parts 39 connected by the connection part 41 of the gate trench portion 40. The trench bottom region 182 may be provided over entire bottom portions of the extension part 29 and the connection part 31 of the dummy trench portion 30.

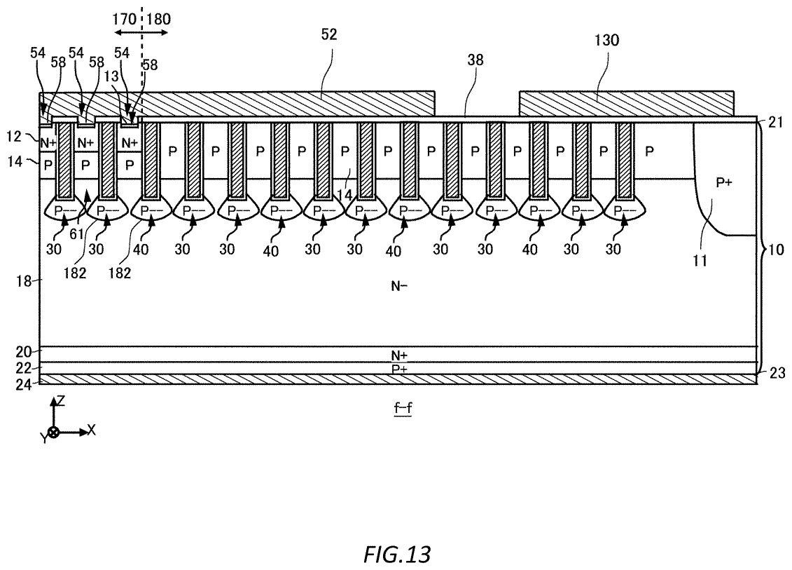

FIG. 13 illustrates another example of the cross section f-f in FIG. 6. The trench bottom region 182 may be provided in contact with bottom portions of all the trench portions in the semiconductor device 100.

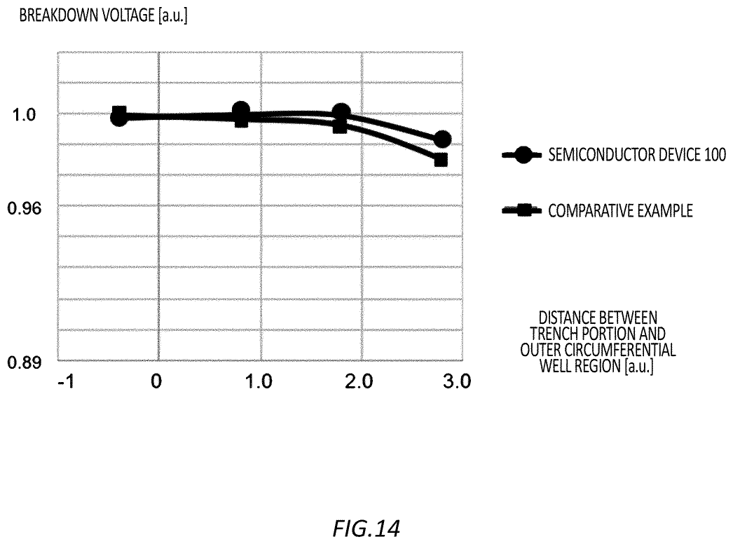

FIG. 14 is a graph representing a relationship of a breakdown voltage [a.u.] with respect to a distance [a.u.] between the trench portion and the outer circumferential well region according to the semiconductor device 100 and a comparative example. A horizontal axis in the graph represents the distance [a.u.] between the trench portion and the outer circumferential well region, and a vertical axis represents the breakdown voltage [a.u.] of the semiconductor device.

As described above, according to the semiconductor device 100, by setting the difference between the end portion of the gate trench portion 40 and the end portion of the dummy trench portion 30 in the trench extension direction to be less than or equal to twice the pitch described above, the region where the trench density decreases in the end portion of the active section 160 in the trench extension direction is not to be provided. In the example of FIG. 14, the distance [a.u.] between the trench portion and the outer circumferential well region 11 in the semiconductor device 100 is changed from −1 [a.u.] corresponding to a partially overlapping state in the top view to 3.0 [a.u.] corresponding to a sufficiently spaced apart state to measure the static breakdown voltage [a.u.] of the trench end of the semiconductor device 100. As a comparative example with the semiconductor device 100, a semiconductor device is prepared in which a region is provided where a difference between the end portion of the gate trench portion and the end portion of the dummy trench portion in the trench extension direction is greater than twice the pitch described above, that is, where the trench density in the end portion of the active section in the trench extension direction decreases, to similarly measure the static breakdown voltage [a.u.]. As represented in the graph of FIG. 14, according to the semiconductor device 100, it may be appreciated that even when the distance between the trench portion and the outer circumferential well region 11 increases compared to the semiconductor device in the comparative example, the static breakdown voltage is stable.

In the plurality of embodiments described above, the configuration has been described in which the trench bottom regions are each individually provided in the bottom portion of corresponding one of the trenches. With regard to all or some of the trench bottom regions in the semiconductor device, the trench bottom regions of the adjacent trench portions may be coupled to each other.

While the present invention has been described by way of the embodiments above, the technical scope of the present invention is not limited to the above-described embodiments. It is apparent to persons skilled in the art that various alterations or improvements can be made to the above-described embodiments. It is also apparent from description of the claims that the embodiments to which such alterations or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate;
11: outer circumferential well region;
12: emitter region;
13: plug region;
14: base region;
15: contact region;
16: accumulation region;
17: anode region;
18: drift region;
20: buffer region;
21: front surface;
22: collector region;
23: lower surface;
24: collector electrode;
29: extension part;
30: dummy trench portion;
31: connection part;
32: dummy insulating film;
34: dummy conductive portion;
38: interlayer insulating film;
39: extension part;
40: gate trench portion;
41: connection part;
42: gate insulating film;
44: gate conductive portion;
52: emitter electrode;
53: barrier metal;
54, 55, 56: contact hole;
58: trench contact portion;
59: plug portion;
60: mesa portion;
61: first mesa portion;
62: second mesa portion;
63: third mesa portion;
64: fourth mesa portion;
70: transistor section;
80: diode section;
81: extension region;
82: cathode region;
90: edge termination structure portion;
92: guard ring;
100: semiconductor device;
130: outer circumferential gate runner;
131: active-side gate runner;
160: active section;
162: end side;
164: gate pad;
170: center portion;
180: outer circumferential portion;
182: trench bottom region;
200: boundary region;
201: first transistor region;
202: second transistor region;
204: lattice defect;
206: lifetime control region;
207: non-adjustment region; and
208: adjustment region.

What is claimed is:

1. A semiconductor device comprising:
a drift region of a first conductivity type which is provided in a semiconductor substrate;
a plurality of trench portions which have a gate trench portion and a dummy trench portion, extend in a predetermined trench extension direction and are arranged at a predetermined pitch in a predetermined trench array direction;
a base region of a second conductivity type which is provided above the drift region;
an emitter region of the first conductivity type which is provided to a front surface of the semiconductor substrate and has a doping concentration higher than that of the drift region;
a plurality of contact regions of the second conductivity type which are provided above the drift region and have a doping concentration higher than that of the base region;
an outer circumferential well region of the second conductivity type which is provided on an outer circumference of the semiconductor substrate relative to the plurality of trench portions;
an interlayer insulating film provided above the semiconductor substrate; and
a gate metal layer connected to the gate trench portion via a contact hole formed in the interlayer insulating film, wherein
the plurality of trench portions are provided to be spaced apart from the outer circumferential well region, and
a difference between an end portion of the gate trench portion and an end portion of the dummy trench portion in the trench extension direction is less than or equal to twice the pitch.

2. The semiconductor device according to claim 1, wherein
the difference is less than or equal to the pitch.

3. The semiconductor device according to claim 2, wherein
the gate trench portion has extension parts which extend in the trench extension direction and a connection part which connects two of the extension parts that are adjacent, and
the difference between the end portion of the gate trench portion in the trench extension direction and the end portion in the trench extension direction of the dummy trench portion provided between the two of the extension parts connected by the connection part is less than or equal to the pitch.

4. The semiconductor device according to claim 1, wherein
the gate trench portion has extension parts which extend in the trench extension direction and a connection part which connects two of the extension parts that are adjacent.

5. The semiconductor device according to claim 4, wherein
the dummy trench portion that is not provided between the two of the extension parts connected by the connection part is provided extending in the trench extension direction beyond an end portion of each of the extension parts.

6. The semiconductor device according to claim 4, wherein
the dummy trench portion that is not provided between the two of the extension parts connected by the connection part is provided extending in the trench extension direction beyond an end portion in the trench extension direction of the dummy trench portion provided between the two of the extension parts connected by the connection part.

7. The semiconductor device according to claim 1, comprising:
trench bottom regions of the second conductivity type which are each provided in contact with a lower end of corresponding one of the plurality of trench portions.

8. The semiconductor device according to claim 2, comprising:
trench bottom regions of the second conductivity type which are each provided in contact with a lower end of corresponding one of the plurality of trench portions.

9. The semiconductor device according to claim 3, comprising:
trench bottom regions of the second conductivity type which are each provided in contact with a lower end of corresponding one of the plurality of trench portions.

10. The semiconductor device according to claim 4, comprising:
trench bottom regions of the second conductivity type which are each provided in contact with a lower end of corresponding one of the plurality of trench portions.

11. The semiconductor device according to claim 5, comprising:
trench bottom regions of the second conductivity type which are each provided in contact with a lower end of corresponding one of the plurality of trench portions.

12. The semiconductor device according to claim 7, wherein
the trench bottom regions are provided extending on an outer side relative to the plurality of contact regions in the trench extension direction.

13. The semiconductor device according to claim 7, wherein
the gate trench portion has extension parts which extend in the trench extension direction and a connection part which connects two of the extension parts that are adjacent, and
the trench bottom regions are each provided in contact with a lower end of the gate trench portion in the connection part.

14. The semiconductor device according to claim 13, wherein
the trench bottom regions are each provided in contact with a lower end of the end portion in the trench extension direction of the dummy trench portion that is not provided between the two of the extension parts connected by the connection part.

15. The semiconductor device according to claim 7, wherein
the trench bottom regions are spaced apart from the outer circumferential well region.

16. The semiconductor device according to claim 15, wherein
an interval between the trench bottom regions and the outer circumferential well region in the trench extension direction is greater than or equal to 4 μm and less than or equal to 14 μm.

17. The semiconductor device according to claim 1, wherein
the dummy trench portion has extension parts which extend in the trench extension direction and a connection part which connects two of the extension parts that are adjacent, and
the semiconductor device comprises an emitter electrode connected to the dummy trench portion via a contact hole provided in each of the two of the extension parts of the dummy trench portion.

18. The semiconductor device according to claim 1, wherein
the gate trench portion has extension parts which extend in the trench extension direction and a connection part which connects two of the extension parts that are adjacent, and
the gate metal layer is connected to each of the two of the extension parts of the gate trench portion.

19. The semiconductor device according to claim 1, comprising:
a trench contact portion which extends in a depth direction of the semiconductor substrate from the front surface of the semiconductor substrate.

20. The semiconductor device according to claim 1, comprising:
a plug region of the second conductivity type which is provided above the drift region and has a doping concentration higher than that of the base region.
